(19) United States
(12) Patent Application Publication
(10) Pub. No.: US 2008/0044967 A1
(43) Pub. Date: Feb. 21, 2008

(54) INTEGRATED CIRCUIT SYSTEM HAVING STRAINED TRANSISTOR

(75) Inventors: Young Way Teh, Singapore (SG); Johnny Widodo, Singapore (SG); Jae Eun Park, Fishkill, NY (US); Michael P. Belyansky, Bethel, CT (US)

Correspondence Address: LAW OFFICES OF MIKIO ISHIMARU, 333 W. EL CAMINO REAL, SUITE 330, SUNNYVALE, CA, 94087, US

(73) Assignees: CHARTERED SEMICONDUCTOR MANUFACTURING LTD., Singapore (SG); SAMSUNG, Gyeonggi-do (KR); INTERNATIONAL BUSINESS MACHINES CORPORATION, Armonk, NY (US)

(21) Appl. No.: 11/465,799

(22) Filed: Aug. 19, 2006

(51) Int. Cl. H01L 21/8238

(52) U.S. Cl. 438/199

(57) ABSTRACT

An integrated circuit system is provided including forming a circuit element on a wafer, forming a stress formation layer on the wafer, protecting a portion of the stress formation layer, and irradiating the wafer for modification of a stress value of an unprotected portion of the stress formation layer.

### TECHNICAL FIELD

The present invention relates to the field of integrated circuits and more specifically to integrated circuit with strained transistor.

### BACKGROUND ART

Modern electronics, such as smart phones, personal digital assistants, location based services devices, digital cameras, music players, servers, and storage arrays, are packing more integrated circuits into an ever shrinking physical space with expectations for decreasing cost. Both higher performance and lower power are also quintessential requirements for electronics to continue proliferation into everyday. For example, more functions are packed into a cellular phone with higher performance and longer battery life. Numerous technologies have been developed to meet these requirements.

Integrated circuits are often manufactured in and on silicon and other integrated circuit wafers. Integrated circuits include literally millions of metal oxide semiconductor field effect transistors (MOSFET). Advances in integrated circuit technology continue to shrink the sizes of these transistors and drive for higher performance with minimum power consumption. This dichotomy has inspired various approaches to solve the need for speed at lower power.

One approach involves continued shrinkage of key features of the integrated circuit technology. This approach provides a size reduction but continues to struggle balancing cost, performance, and power. Another approach involves different integrated circuit materials or material systems, such as silicon on insulator (SOI), silicon germanium (SiGe) material, etc. These alternatives provide some technology improvements but are not mainstream today resulting in higher cost as well as constrain volume capacity.

Yet another approach is to provide performance improvement and power reduction while controlling cost. This approach squeezes as much performance, power, or both out of a given integrated circuit technology and manufacturing through a technique called “strained” transistors. This allows use of existing integrated circuit manufacturing and technology investments to keep the cost down or extend future technology generations.

There are various strained integrated circuit approaches. Some approaches use different material systems as the SOI mentioned earlier. Again, these different material systems provide technology improvements but add cost and are not available in volume to satisfy the high volume modern electronics needs. Other “strained” approaches use mainstream integrated circuit technology and manufacturing, such as complementary metal oxide semiconductor (CMOS).

One area where the paradox of performance, power, and cost is most evident in the modem Ultra-Large Scale Integration era is in the microprocessor. The microprocessor in one form or another permeates modern electronics. Microprocessor applications need faster transistor speeds and high drive currents. Microprocessor integrated circuit technologies have seen many transistor designs and processing schemes to improve the mobility of carriers to improve performance and lower power consumption. One way to achieve faster switching of a MOS transistor is to design the device with “strained” transistors so that the mobility and velocity of its charge carriers in the channel region are increased.

An appropriate type of stress in the channel region of an n-channel metal oxide semiconductor (NMOS) transistor is known to improve carrier mobility and velocity, which results in increased drive current for the transistor. High tensile material such as silicon nitride supplies a tensile stress in the NMOS region beneath the tensile layer. In order to maintain the performance of PMOS devices, a germanium (Ge) implant process is used to relax the material covering the PMOS device. A resist layer covering the NMOS devices blocks this implant and maintains the tensile stress in the NMOS channel. These techniques are essential in the efforts to develop faster products.

To achieve performance improvement and power reduction in a CMOS device, both the PMOS transistor and the NMOS transistor need to be strained. The PMOS transistor must be strained to provide compression stress to the p-channel while the NMOS transistor must be strained to provide tensile stress to the n-channel. Typically, dual stress liners (DSL) or dual stress contact etch stop liner may be used to accommodate the different stress requirements. The DSL technique has complicated process and integration issues, such as silicide loss and poor contact at the DSL overlap region.

Thus, a need still remains for improving the yield and cost of the basic transistor structures and manufacturing to obtain maximum performance improvement, power reduction, or both. In view of the demand for faster microprocessors and memory devices, it is increasingly critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including forming a circuit element on a wafer, forming a stress formation layer on the wafer, protecting a portion of the stress formation layer, and irradiating the wafer for modification of a stress value of an unprotected portion of the stress formation layer.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit system in an embodiment of the present invention;

FIG. 2 is a cross-sectional view of the integrated circuit system in a deposition phase of the stress formation layer;

FIG. 3 is a cross-sectional view of the structure of FIG. 2 in a pattern and etch phase;

FIG. 4 is a cross-sectional view of the structure of FIG. 3 in a radiation phase;

FIG. 5 is a cross-sectional view of the structure of FIG. 4 in a protective application phase; and

FIG. 6 is a flow chart of an integrated circuit system for manufacture of the integrated circuit system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

The term “processing” as used herein includes deposition of material, patterning, exposure, development, etching, cleaning, molding, and/or removal of the material or as required in forming a described structure.

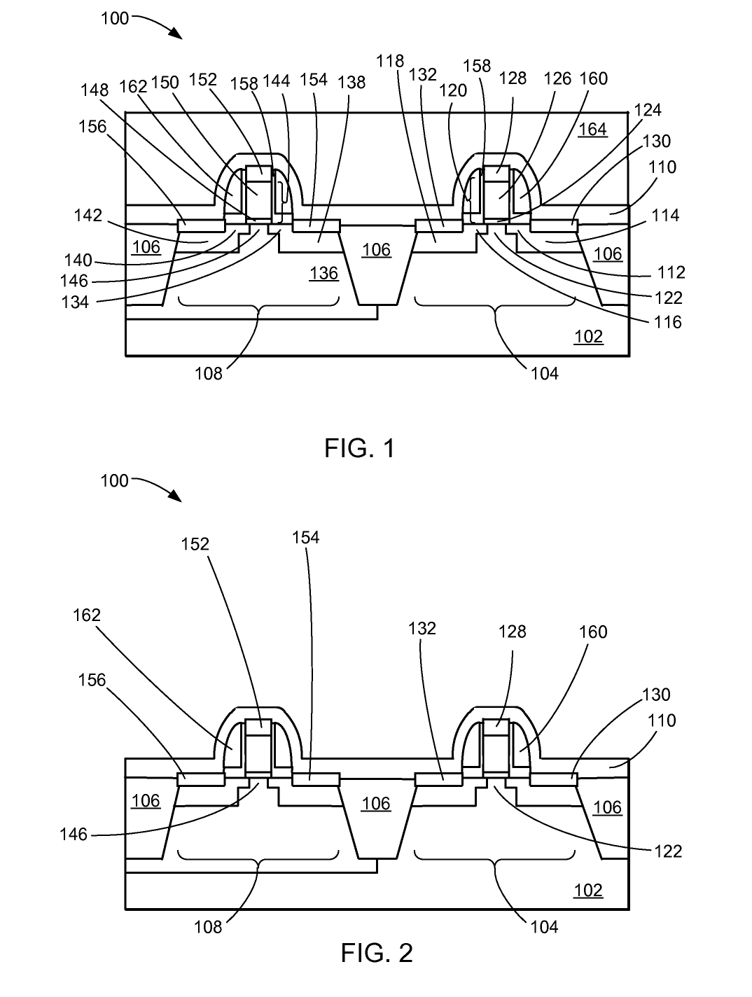

Referring now to FIG. 1, therein is shown a cross-sectional view of an integrated circuit system 100 in an embodiment of the present invention. The integrated circuit system 100 includes a wafer 102, such as a p-type substrate wafer, having a first circuit element 104, isolation regions 106, a second circuit element 108 and a stress formation layer 110, such as a compression layer of nitride or silicon nitride.

The first circuit element 104, such as an n-type metal oxide semiconductor (NMOS) transistor, includes a first source 112 formed in the wafer 102. The first source 112, such as an n-type source, includes a first source region 114 implanted into the wafer 102. A first drain 116 is formed in the wafer 102, wherein the first drain 116 includes a first drain region 118 implanted into the wafer 102. For illustrative purposes, the first circuit element 104 is shown as a transistor, although it is understood that the first circuit element 104 may be any passive circuit element, active circuit element, or any structures, such as routing lines on the wafer 102.

A first gate stack 120 is formed on the surface of the wafer 102 and over a first channel region 122. The first channel region 122 is part of the wafer 102 and between the first source 112 and the first drain 116. The first gate stack 120 includes a first gate oxide 124, such as a thin gate oxide with high-K dielectric, and a first gate electrode 126.

An oxide liner 158 is formed adjacent to the first gate stack 120 over the first source 112 and the first drain 116. A first spacer 160 is formed on the oxide liner 158 surrounding the first gate stack 120 as well as over the first source 112 and the first drain 1 16.

A silicide layer is formed over the first gate stack 120, the first source region 114 and the first drain region 118. A first gate contact 128, a first source contact 130 and a first drain contact 132 are formed from the silicide layer. The first spacer 160 is used to block the deposition of the silicide layer adjacent to the first gate stack 120 to electrically isolate the first source contact 130 and the first drain contact 132 from the first gate stack 120. The first source contact 130 connects with the first source region 114. The first drain contact 132 connects with the first drain region 118.

The second circuit element 108, such as a p-type metal oxide semiconductor (PMOS) transistor, includes a second source 134 formed in a well region 136, such as an n-type well. The well region 136 is in the wafer 102. The second source 134 includes a second source region 138 implanted into the well region 136. A second drain 140 is formed in the well region 136 includes a second drain region 142 implanted into the well region 136. For illustrative purposes, the second circuit element 108 is shown as a transistor, although it is understood that the second circuit element 108 may be any passive circuit element, active circuit element, or any structures, such as routing lines on the wafer 102.

A second gate stack 144 is formed on the wafer 102 and over a second channel region 146. The second channel region 146 is part of the well region 136 located between the second source 134 and the second drain 140. The second gate stack 144 includes a second gate oxide 148, such as a thin gate oxide with high-K dielectric, and a second gate electrode 150.

The oxide liner 158 is formed adjacent to the second gate stack 144 over the second source 134 and the second drain 140. A second spacer 162 is formed on the oxide liner 158 surrounding the second gate stack 144 as well as over the second source 134 and the second drain 140.

The silicide layer is formed over the second gate stack 144, the second source region 138 and the second drain region 142. A second gate contact 152, a second source contact 154 and a second drain contact 156 are formed from the silicide layer. The second gate contact 152 is on the second gate electrode 150. The second spacer 162 is used to block the deposition of the silicide layer adjacent to the second gate stack 144 to electrically isolate the second source contact 154 and the second drain contact 156 from the second gate stack 144. The second source contact 154 connects with the second source region 138. The second drain contact 156 connects with the second drain region 142.

The stress formation layer 110 lines the surface of the first circuit element 104, the second circuit element 108, and the isolation regions 106. The stress formation layer 110 may perform different functions, such as provide compression or tensile stress, for the first circuit element 104 and the second circuit element 108.

The stress formation layer 110 over the first circuit element 104 provides compression to the first channel region 122. This compression stress strains the first channel region 122 to increase charge, such as holes, mobility thereby increasing performance, lowering power consumption, or both.

The stress formation layer 110 over the second circuit element 108 is stressed with increased tensile stress, compared to the first circuit element 104, or provides neutralized compression to the second channel region 146. The tensile stress strains the second channel region 146 to increase charge, such as electrons, mobility thereby increasing performance, lowering power consumption, or both. An interlayer dielectric 164 forms over the stress formation layer 110 protecting the first circuit element 104 and the second circuit element 108 as well as the rest an active side of the wafer 102 for further processing.

Referring now to FIG. 2, therein is shown a cross-sectional view of the integrated circuit system 100 in a deposition phase of the stress formation layer 110. The wafer 102 includes the first circuit element 104 and the second circuit element 108. The stress formation layer 110 covers the active side of the wafer 102.

The stress formation layer 110 is deposited over the first gate contact 128, the first spacer 160, the first source contact 130, and the first drain contact 132. The stress formation layer 110 is also deposited over the second gate contact 152, the second spacer 162, the second source contact 154, and the second drain contact 156. The isolation regions 106 are also covered by the stress formation layer 110.

The first circuit element 104 as an NMOS transistor has the first channel region 122 with enhanced stress memory for increased charge, such as electron, mobility. The stress formation layer 110 as a compressive layer including nitride or silicon nitride decreases electron mobility in the first channel region 122 as an n-channel. The second circuit element 108 as a PMOS transistor benefits from the compression stress from the stress formation layer 110 to improve hole mobility in the second channel region 146.

For illustrative purposes, the stress formation layer 110 is described as providing compression stress, although it is understood that the stress from the stress formation layer 110 may be selected by adjusting the silicon nitride material to have a stress values ranging from compressive to tensile stresses. The selection of the stress type in the silicon nitride material selects the type of strain provided to the first channel region 122.

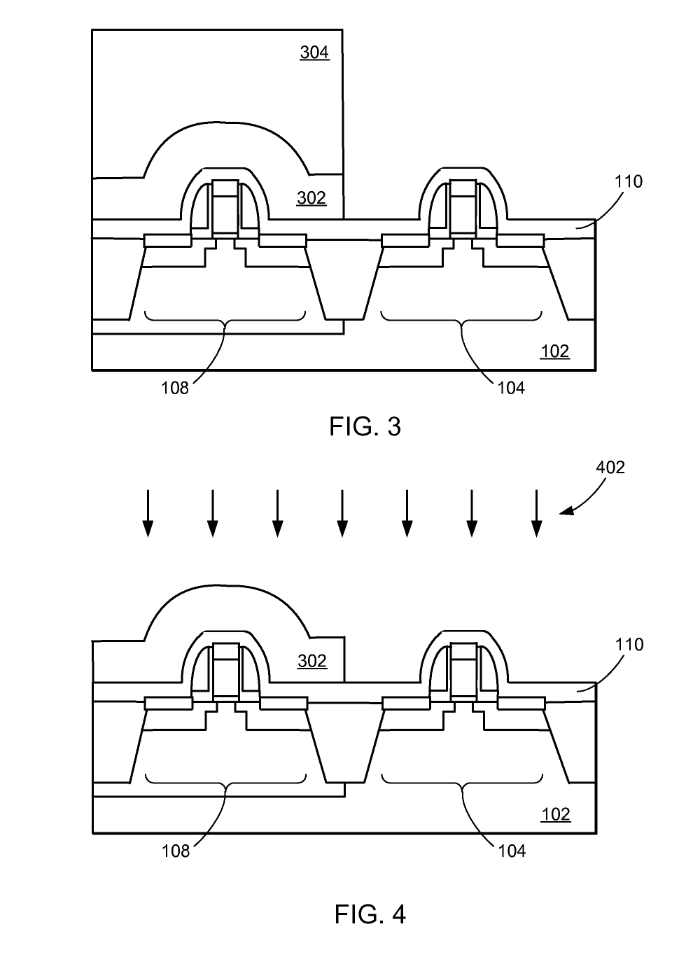

Referring now to FIG. 3, therein is shown a cross-sectional view of the structure of FIG. 2 in a pattern and etch phase. A first interlayer dielectric 302, such as a silicon dioxide layer (SiO₂), is deposited over the stress formation layer 110 and over the active side of the wafer 102. The first interlayer dielectric 302 may have a thickness range, such as one kiloangstrom to two kiloangstrom.

A mask 304 is formed over the first interlayer dielectric 302 and across the active side of the wafer 102. The mask 304 and the first interlayer dielectric 302 is selectively etched away exposing the stress formation layer 110 over the first circuit element 104. The stress formation layer 110 also functions as a contact etch stop liner in this phase. The mask 304 and the first interlayer dielectric 302 covers the second circuit element 108.

Referring now to FIG. 4, therein is shown a cross-sectional view of the structure of FIG. 3 in a radiation phase. The wafer 102 undergoes strip and clean resist off removing the mask 304 of FIG. 4. The first interlayer dielectric 302 remains over the stress formation layer 110 covering the second circuit element 108. The stress formation layer 110 remains over the first circuit element 104.

The wafer 102 undergoes a radiation treatment 402, such as an ultraviolet (UV), an electronic bean (e-beam), or a radio frequency (RF) treatment, on the active side. The first interlayer dielectric 302 blocks the ultraviolet radiation to protect the stress formation layer 110 over the second circuit element 108. The compression stress of the stress formation layer 110 over the second circuit element 108 is not diminished.

The ultraviolet radiation relaxes the compression stress of the stress formation layer 110 not protected by the first interlayer dielectric 302. The stress formation layer 110 over the first circuit element 104 relaxes from a compression stress to a neutral or to even a tensile stress on the first circuit element 104.

Generally, the tensile stress of an as-deposited silicon nitride material can be increased by treating the deposited material with exposure to a suitable energy beam, such as ultraviolet radiation or electron beams. It is believed that ultraviolet and electron beam exposure can be used to further reduce the hydrogen content in the deposited material.

A suitable ultraviolet radiation source can emit a single ultraviolet wavelength or a broadband of ultraviolet wavelengths. A suitable single wavelength ultraviolet source includes an excimer ultraviolet source that provides a single ultraviolet wavelength of 172 nm or 222 nm. A suitable broadband source generates ultraviolet radiation having wavelengths of from about 200 to about 400 nm.

Generation of ultraviolet radiation specifically tailored to modify the stress value in the deposited stressed material can be accomplished by introducing a mixture of gases into the lamp, each gas capable of emitting radiation of a characteristic wavelength upon excitation. By varying the relative concentration of the gases, the wavelength content of the output from the radiation source can be selected to simultaneously expose all of the desired wavelengths, thus minimizing the necessary exposure time. The wavelength and intensity of the ultraviolet radiation can be selected to obtain predetermined tensile stress value in the deposited silicon nitride material For deposited films, ultraviolet radiation exposure increases tensile stress values, with the greatest improvement occurring for the materials having the lowest tensile stress values.

The exposure of the deposited silicon nitride (SiN) material to ultraviolet radiation or electron beams is capable of reducing the hydrogen (H) content of the deposited material, and thereby increasing the tensile stress value of the material. The exposure to ultraviolet radiation allows replacement of unwanted chemical bonds with more desirable chemical bonds. For example, the wavelength of UV radiation delivered in the exposure may be selected to disrupt unwanted hydrogen bonds, such as the Si—H and N—H bond that absorbs this wavelength. The remaining silicon atom then forms a bond with an available nitrogen atom to form the desired Si--N bonds.

The ultraviolet treatment form the resultant silicon nitride material with fewer N—H and Si—H bonds, and an increased number of Si—N bonds which are desirable to increase the tensile stress of the deposited material. A broadband ultraviolet radiation source increases tensile stress in the deposited material as compared with a single wavelength ultraviolet radiation source. As ultraviolet treatment time increases, the tensile stress of the as-deposited film also increases.

The as-deposited silicon nitride material can also be treated by exposure to an electron beam. The electron beam exposure conditions depend upon the total dosage applied, the electron beam energy applied to the deposited material, and the electron beam current density. The dose and energy selected will be proportional to the thickness of the deposited material to be processed. The dosage energy of electrons provided by the electron beam can also be selected to obtain predetermined stress value in the deposited silicon nitride material. The tensile stress values increases with electron beam treatment.

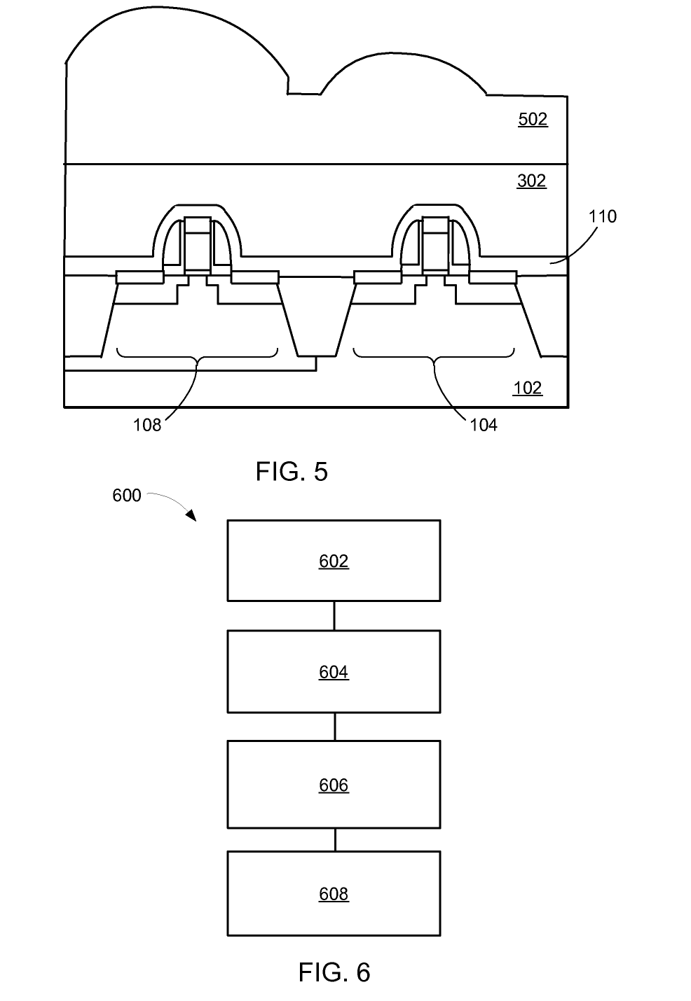

Referring now to FIG. 5, therein is shown a cross-sectional view of the structure of FIG. 4 in a protective application phase. A second interlayer dielectric 502, such as a silicon dioxide layer (SiO₂), is deposited on the active side of the wafer 102. The second interlayer dielectric 502 is over the first interlayer dielectric 302 above the second circuit element 108. The stress formation layer 110 over the first circuit element 104 is also covered by the second interlayer dielectric 502. The thickness of the second interlayer dielectric 502 may be a range, such as six kiloangstrom to seven kiloangstrom.

The second interlayer dielectric 502 undergoes planarization, such as chemical mechanical planarization (CMP), to flatten all the topography. The planarization forms integrated circuit system 100 ready for further processing.

Alternatively, the stress formation layer 110 may be a neutral contact etch stop liner. A similar radiation process may be applied on the stress formation layer 110 over the second circuit element 108 with the first circuit element 104 protected by an interlayer dielectric (not shown). The radiation process, such as an ultraviolet or e-beam treatment, will modify the neutral stress of the stress formation layer 110 over the second circuit element 108 to be more tensile. The stress formation layer 110 protected by the interlayer dielectric remains neutral stress. The stress formation layer 110 over the second circuit element 108 may be embedded with silicon germanium (SiGe) before the interlayer dieclectric deposition. The silicon germanium modifies the neutral stress of the stress formation layer 110 to be compressive.

The radiation treatment 402 may also be used to increase the compression stress in the stress formation layer 1 10. Deposition process and treatment conditions can be tailored to deposit a compressive stressed material on the wafer 102 or to treat a material during or after deposition to increase its compressive stress value. A silicon nitride stressed material having higher compressive stress values can be obtained by increasing the radio frequency bombardment to achieve higher film density by having more Si—N bonds in the deposited material and reducing the density of Si—H and N—H bonds. Higher deposition temperatures and RF power improve the compressive stress levels of the stress formation layer 110.

Application of a combination of both low and high radio frequency power levels generate the highest compressive stress values. Further enhanced compressive stress values may be achieved at higher power levels of both the low and high RF voltages. For low RF voltages, the power levels may be at least about 50, and more preferably from about 100 to about 400 Watts. Suitable power levels for the high RF voltages were at least about 100, and more preferably from about 200 to about 500 Watts.

Referring now to FIG. 6, therein is shown a flow chart of an integrated circuit system 600 for manufacture of the integrated circuit system 100 in an embodiment of the present invention. The system 600 includes forming a circuit element on a wafer in a block 602; forming a stress formation layer on the wafer in a block 604; protecting a portion of the stress formation layer in a block 606; and irradiating the wafer for modification of a stress value of an unprotected portion of the stress formation layer in a block 608.

It has been discovered that the present invention thus has numerous aspects.

It has been discovered that radiation treatments, stressed materials, or a combination simplifies forming strained transistors for improved performance and lower power.

An aspect of the present invention is that the circuit elements, such as transistors, across the wafer can be stressed to the desired state for the performance, power, or both. The transistors may be stressed to have tensile stress, compression stress, neutral stress, varying degrees and combination of stresses.

Another aspect of the present invention is the complementary or opposing stress requirements may be achieved by the selection of the stressed materials, mask patterns, and radiation treatments.

Yet another important aspect of the present invention is that the stress value may be further enhanced with selection of the stressed materials and additional processing, such as embedding silicon germanium or stressed memory technique, along with the radiation treatment.

Yet another important aspect of the present invention is that the stress value may be further enhanced with a combination of frequencies or wavelength of a given radiation treatment to stressed materials.

Yet another important aspect of the present invention is that the stress value may vary across the wafer in a predetermined pattern depending on the mask patterns and exposure steps, type of stressed materials, type of radiation, time of radiation exposure, frequencies of radiation, frequency mix, and the power of the radiation.

Yet another important aspect of the present invention is that radiation treatment in conjunction with mask patterns improves the control to modify the stress value of the stress materials. The mask patterns may minimizes boundary regions of the between the stress materials at opposing stress requirements. This reduction of the boundary regions increases the flexibility to scale the integrated circuit technologies to smaller geometries.

Yet another important aspect of the present invention is that the stressed materials may be applied to other structures, such as routing lines, on the wafer. The stress values of portions of the stressed materials may be selectively modified to selected structures on the wafer.

Yet another important aspect of the present invention is that the stressed material may be applied to internal and external structures and circuits of dice on the wafer. External structures, such as input/output cells or protection structures, may also undergo selective stress value modification.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system method and apparatus of the present invention furnish important and heretofore unknown and unavailable solutions, capabilities, and functional aspects for integrated circuit systems. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit system comprising:
forming a circuit element on a wafer;
forming a stress formation layer on the wafer;
protecting a portion of the stress formation layer; and
irradiating the wafer for modification of a stress value of an unprotected portion of the stress formation layer.

2. The system as claimed in claim 1 wherein the irradiating includes applying ultraviolet treatment, e-beam treatment, radio frequency treatment, or a combination thereof.

3. The system as claimed in claim 1 wherein the irradiating includes varying an exposure time, a wavelength, a power level, a voltage level, or a combination thereof of a radiation treatment on the wafer.

4. The system as claimed in claim 1 wherein forming the circuit element includes forming a passive circuit element, an active circuit element, or a routing trace on the wafer.

5. The system as claimed in claim 1 wherein forming the stress formation layer includes forming a layer comprised of a compression stressed material, a tensile stressed material, or a neutrally stressed material.

6. An integrated circuit system comprising:
forming a first transistor and a second transistor on a wafer;
depositing a stressed material comprised of nitride over the wafer including the first transistor and the second transistor;
protecting a portion of the stressed material over the second transistor; and
irradiating the wafer for modification of a stress value of an unprotected portion of the stressed material over the first transistor.

7. The system as claimed in claim 6 wherein depositing the stressed material includes depositing the stressed material comprised of silicon.

8. The system as claimed in claim 6 wherein irradiating the wafer for modification of the stress value of the unprotected portion of the stressed material over the first transistor includes modifying a channel structure of the first transistor for performance improvement.

9. The system as claimed in claim 6 wherein protecting the portion of the stressed material over the second transistor includes protecting the second transistor from a radiation treatment.

10. The system as claimed in claim 6 wherein forming the first transistor and the second transistor includes forming a complementary metal oxide semiconductor transistor pair.

11. An integrated circuit system comprising:
a circuit element on a wafer;
a stress formation layer on the wafer;
a mask over a portion of the stress formation layer; and
an unprotected portion of the stress formation layer having a radiation modified stress value.

12. The system as claimed in claim 11 wherein the circuit element includes a passive circuit element, an active circuit element, or a routing trace on the wafer.

13. The system as claimed in claim 11 wherein the circuit element on the wafer includes an external circuit element of an integrated circuit die on the wafer.

14. The system as claimed in claim 11 wherein the mask comprises an interlayer dielectric.

15. The system as claimed in claim 11 wherein the stress formation layer is a layer comprised of a compression stressed material, a tensile stressed material, or a neutrally stressed material.

16. The system as claimed in claim 11 wherein:
the circuit element has a first transistor and a second transistor on the wafer;
the stress formation layer is comprised of a nitride stress material on the wafer;
the mask includes an interlayer dielectric over the portion of the stress formation layer; and
the unprotected portion of the stress formation layer having a radiation modified stress value is over the first transistor.

17. The system as claimed in claim 16 wherein the stressed material is comprised of silicon.

18. The system as claimed in claim 16 wherein the unprotected portion of the stress formation layer having the radiation modified stress value has a channel structure, modified, of the first transistor for performance improvement.

19. The system as claimed in claim 16 wherein the mask over the portion of the stress formation layer is over the second transistor.

20. The system as claimed in claim 16 wherein the first transistor and the second transistor are a complementary metal oxide semiconductor transistor pair.
